(19) United States
(12) Patent Application Publication
(10) Pub. No.: US 2011/0096495 A1
(43) Pub. Date: Apr. 28, 2011

(54) CIRCUIT BOARD ARRANGEMENT FOR THERMALLY STRESSED ELECTRONIC COMPONENTS, IN PARTICULAR IN MOTOR VEHICLE CONTROL APPARATUS

(75) Inventor: Andreas Heise, Erzhausen (DE)

(73) Assignee: CONTINENTAL TEVES AG & CO. OHG, Frankfurt (DE)

(21) Appl. No.: 12/994,286

(22) PCT Filed: May 26, 2009
(86) PCT No.: PCT/EP2009/056359

§ 371 Date: Nov. 23, 2010

(30) Foreign Application Priority Data
May 26, 2008 (DE) 10 2008 025 078.3
May 20, 2009 (DE) 10 2009 022 110.7

(51) Int. Cl. H05K 7/20; H05K 3/30

(52) U.S. Cl. 361/688; 29/832

(57) ABSTRACT

Circuit board arrangement, in particular multiple layer circuit board arrangement with at least one low-power circuit path, wherein the circuit board arrangement is suitable for population with at least one electronic circuit board element to be cooled, wherein the circuit board consisting of a nonconductive material includes at least one cooling inlay embedded in the circuit board for cooling of the power component, wherein the cooling inlay forms at least in part, a high power guide element for the at least one electronic power component, wherein the line cross section or the power carry capacity of the high power guide element is significantly greater than the line cross section or the current carry capacity of the low power circuit path, and wherein the high power guide element is used and/or is also used for electrical contacting of the power component.

### CROSS REFERENCE TO RELATED APPLICATIONS

This application is the U.S. national phase application of PCT International Application No. PCT/EP2009/056359, filed May 26, 2009, which claims priority to German Patent Application No. 10 2008 025 078.3, filed May 26, 2008, and German Patent Application No. 10 2009 022 110.7, filed May 20, 2009, the contents of such applications being incorporated by reference herein.

### FIELD OF THE INVENTION

The invention relates to a circuit board arrangement, the use of said circuit board arrangement, and also a method for producing said circuit board arrangement.

### BACKGROUND OF THE INVENTION

Circuit board arrangements with heat sinks are already known. Circuit board arrangements which are suitable simultaneously for the placement of electronic components for switching or regulating high powers and for population with components having only a low conduction loss are furthermore known.

EP 1 929 847 A1, which is incorporated by reference, which forms the generic type, discloses a multilayer circuit board, comprising cooling inlays for cooling power components using SMD technology. This known circuit board arrangement is specifically designed for applications in radiofrequency technology and comprises, for cooling purposes, inlays that are three times as large as the electronic component to be cooled. In order not to bring about a short circuit at the connection legs of the electronic power component to be cooled, an insulating, thin intermediate layer is applied between cooling inlay and component.

The requirements present in the field of motor vehicle technology are not, or not sufficiently, fulfilled by the known circuit board arrangement described above.

In the field of motor vehicle technology and also power electronics, hitherto use has often been made of a hybrid technology in which two separate circuit boards with different technologies are used for the power electronics and for the rest of the microelectronic circuit. The separate circuit boards are generally connected by bonding. As an alternative to the hybrid technology, so-called leadframe technology is also already employed, in which the electronic components are welded or riveted on a leadframe. The leadframes themselves are then often connected to the other circuit components by bonding again. Besides the technologies described above, there is also the requirement for optimally cooling the power components, which often takes place by means of complicated adhesive bonding technology or paste applications e.g. of the hybrid circuit boards.

The connection technologies described above generally require a very complicated and costly production process. Moreover, structural space required is still too large for present-day requirements.

As already mentioned further above in connection with EP 1 929 847 A1, it is known, for the purpose of cooling electronic components and multilayer circuit boards, to introduce copper blocks in the form of inlays into a corresponding cutout in the circuit board (so-called heat sinks). These cooling inlays can be shaped in different ways and fulfil a similar function to thermovias, known per se, but with a significantly lower thermal resistance. Thus, by way of example, round or else polygonal inlays are known per se.

### SUMMARY OF THE INVENTION

The invention is concerned with the object of specifying a circuit-board and contact-connection technology which better fulfils the above-described requirements in respect of thermal conductivity and current-carrying capacity and manages without an intermediate layer between cooling inlay and electrical power component to be cooled.

This object is achieved by means of the circuit board arrangement comprising at least one low-current conductor track, wherein the circuit board arrangement is suitable for population with a least one electronic power component to be cooled, wherein the circuit board consisting of a nonconductive material comprises at least one cooling inlay embedded into the circuit board and serving for cooling the power component, wherein the cooling inlay forms, at least in part, a high-current conducting element for the at least one electronic power component, wherein the conducting cross section or the current-carrying capacity of the high-current conducting element is significantly higher than the conducting cross section or the current-carrying capacity of the low-current conductor track, and wherein the high-current conducting element is utilized and/or concomitantly utilized for making electrical contact with the power component.

The circuit board arrangement is embodied in a multilayered fashion, in particular, and comprises at least one low-current conductor track and also at least one high-current conducting element, which is at least partly formed by a cooling inlay. Therefore, at least one cooling inlay is directly or indirectly electrically connected to an electronic power component to be cooled. The conducting cross section or the current-carrying capacity of the high-current conducting element is significantly higher than the conducting cross section of the current-carrying capacity of the low-current conductor track. Preferably, the circuit board arrangement additionally also comprises at least one low-current component.

According to aspects of the invention, at least one cooling inlay is introduced into a circuit board. When considered in the cross section of the circuit board relative to the thickness, the cooling inlay preferably occupies at least approximately 90% of the circuit board thickness. Particularly preferably, the cooling inlay has a thickness that almost corresponds to the thickness of the circuit board, so that the cooling inlay terminates almost flush with the surface of the circuit board. The cooling inlay occupies a largest possible volume for the purpose of high current conductivity and thermal conductivity. Therefore, expediently, the extent of a cooling inlay in the direction of the circuit board plane is at least greater than half of its height. Particularly preferably, however, the extent of the cooling inlay in the circuit board plane is at least equal to or greater than the thickness of said inlay. For making contact with the electronic components, preferably a plurality of cooling inlays that are electrically insulated from one another are introduced into the circuit board, such that the high-current paths can be utilized not only for cooling but also for transporting the current for power components.

The cooling inlay can be embodied in a solid or hollow fashion. In the case of a hollow embodiment, preferably a liquid flows through or fills the cooling inlay. A throughflow of the liquid is advantageous for the purpose of convection that promotes the heat exchange. It is also possible and particularly expedient for the composition of the liquid or of some other suitable solid filling material to be chosen such that, in the case of a temperature change, a change in the state of matter of the liquid or of the filling material takes place, in the case of which heat is absorbed or emitted by the liquid or the filling material. Preferably, however, the cooling inlay consists for the most part or wholly of metal and can be constructed in a solid pressure or in a coated fashion. Identical of different materials are used here depending on the application. Cu, Al, Ag or Au is particularly suitable as metallic material for the cooling inlay or the coating, wherein Cu or Al is preferred in the case of the solid construction of a cooling inlay.

Preferably, no insulating intermediate layer is present between the cooling inlay and the power component to be cooled, with the result that, by virtue of the close contact between thermally stressed electronic component and cooling inlay, higher heat dissipation than in the case of arrangements with an intermediate layer is possible and the manufacturing process is simplified. In this case, the surface of the cooling inlay, on the placement side, is preferably configured such that it is almost flush with the circuit board surface. Expediently, the cooling inlay, if it penetrates through the entire diameter, is configured such that it is flush with the surface of the circuit board also on the opposite circuit board surface.

The contact-connection arrangement preferably also comprises an electrical high-current connection technique of a first type into the cooling inlays, for example by means of press-fit pins. Preference is furthermore given to a contact-connection technique by means of press-fit pins of a second type for the weaker currents of low-power circuits (e.g. signal circuits, logic circuits or microelectronic circuits) which, in particular, lead into the circuit board in order to produce a contact-connection of surface conductor tracks and/or a contact-connection to low-current conductor tracks lying internally in the circuit board.

The high-current conducting element is preferably connected to at least one further electronic power component or a high-current contact-connection in an electrically conductive and low-impedance manner.

The circuit board is advantageously suitable for being used in a conventional SMD mounting process in which joint placement of electrical power components and low-power components is effected.

Preferably, the circuit board arrangement is provided for the use of press-fitted contact elements and/or screwed-in contact elements and/or plugged-in contact elements by virtue of corresponding cutouts or couplings being introduced into the cooing inlays and/or the circuit board. Particularly advantageously, these coupling locations are designed such that a high outflow of heat can be ensured.

In the cooling inlays, in accordance with one preferred embodiment, contact-connection holes are provided in a pattern or hole grid suitable for plug pins in order that a plug can be directly electrically connected to the circuit board or to the cooling inlay(s) arranged therein. As a result, the contact region of the connection plug can be cooled particularly effectively or hardly any heat losses arise at the transition locations.

The cooling inlays preferably consist of a metal, in particular of copper. In this case, it is particularly expedient to tin-plate, to silver-plate or to gold-plate the cooling inlays for better solderability prior to insertion into the circuit board. This coating can, in particular, also be performed during the circuit board production process. In this case, it is especially expedient if a in defined regions a coating that impedes soldering (e.g. soldering resist) is applied to the cooling inlay in order to simplify the mounting of the electronic components.

Direct connections by means of a pressure contact, soldering, welding, calking or similar techniques are appropriate as electrical connection techniques used. Preference is given to using substantially predominantly or exclusively SMD soldering together with the press-fit technique.

According to one preferred embodiment, for the electrical connection of the cooling inlays arranged on the circuit board in insulated regions, high-current bridges or busbars are supplied to the circuit board, wherein the high-current bridges are expediently fixed using the connection techniques mentioned above. Conductor runs having high-current capability and with, in addition, high thermal conductivity are obtained in this way.

In accordance with a further preferred embodiment, the high-current conducting element, in particular a cooling inlay, has the form of a complex conductor track, such that it is multiply branched and/or multiply curved and/or provided with multiple connection locations for the electrical components. Expediently, the high-current conducting element has one or a plurality of joining points which can be used to form positively locking connections to the conductor track or parts thereof, wherein the joining points constitute dovetail connections or similar connections. By virtue of the form of the joining point, a connection can be produced in a particularly simple and hence advantageous manner without a cohesive or force-locking connection, merely by means of the positively locking connection.

The circuit board arrangement described above makes it possible to transport electric currents in the range of preferably more than 10 Å, in particular more than 30 Å, via the high-current conductor tracks.

The invention additionally relates to a method for producing the circuit board arrangement described above, in which at least one cooling inlay is press-fitted into a circuit board arrangement, comprising at least one low-current conductor track, by means of a machine before, in a further step, the circuit board arrangement is populated with electrical components according to the SMD method.

In accordance with the method it is preferred to apply a coating the impedes soldering before or after the press-fitting of the cooling inlay on the surface thereof in defined regions.

It has been found that it is expedient, in the case of a cooling inlay with a stamped hole or drilled hole, to apply no soldering paste or soldering tin on said cooling inlay, in order to improve the function and security of the press-fit connection.

The circuit board arrangement according to aspects of the invention is preferably part of a housing for control apparatus and inserted into said housing in particular completely or partly by means of press-fit technology. In this case, depending on the required current-carrying capacity, press-fit contacts of different sizes can be used, wherein the larger press-fit contacts are then inserted, at least in part, directly into cutouts of cooling inlays. It is expedient to use for this purpose, for example, a larger and a smaller standard type for press-fit contacts. The circuit board arrangement and the housing for control apparatus are preferably used in electronic systems of motor vehicles.

### BRIEF DESCRIPTION OF THE DRAWINGS

The invention is best understood from the following detailed description when read in connection with the accompanying drawings. Included in the drawings is the following figures:

FIGS. 1a and 1b show a circuit board with introduced cooling inlays,

FIGS. 2a and 2b show a circuit board with round cooling inlays,

FIGS. 3-6 show different possibilities for populating the circuit board with electronic components,

FIGS. 7 and 8 in each case show a circuit board in cross section,

FIGS. 9 and 10 in each case show a circuit board with a press-fit contact,

FIG. 11 shows a circuit board with a screw,

FIG. 12 shows a circuit board with a complexly shaped cooling inlay,

FIG. 13 shows a circuit board with additional cooling and

FIG. 14 shows a circuit board with a socket contact.

### DETAILED DESCRIPTION OF THE PREFERRED EMBODIMENTS

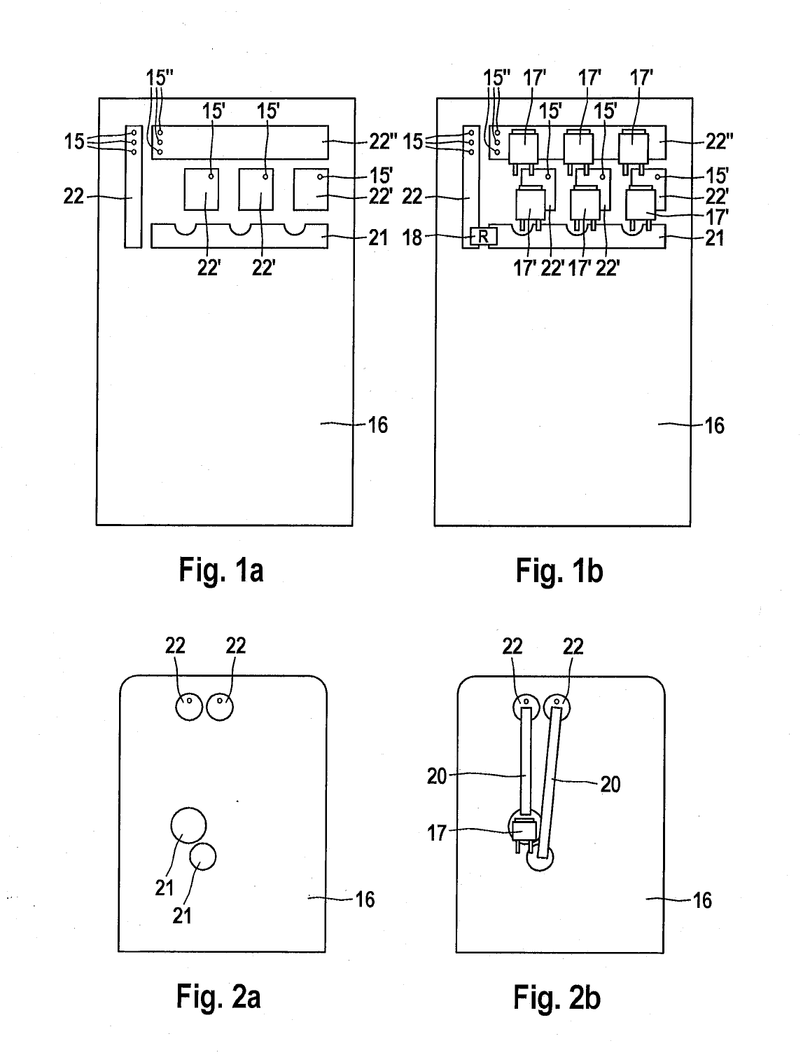

FIG. 1a shows a circuit board 16 comprising a plurality of cooling inlays 21, 22, 22′ and 22″ composed of solid Cu that are incorporated in the circuit board. Two cooling inlays 21, 22″ have contact holes 15 and 15″, respectively, for the purpose of contact-connection by means of the press-fit or plugging technique described further below. In this way, e.g. a voltage supply of a load, such as, for instance, that of an electric motor, can be connected to the circuit board.

FIG. 1b shows the same circuit board 16 comprising power SMD components 17, 17′ and 18 placed using SMD technology. The electrical components 17, 17′ and 18 are placed or soldered, for cooling purposes, by their cooling area onto the cooling inlays. In this case, at least some of the connection legs of the power SMD components are connected to a cooling inlay. Other SMD components required for the operation of the circuit are not illustrated, for the sake of simplicity.

The current-carrying connections of the power semiconductor components 17 are thereby led with a busbar-heat sink inlay 22″ as far as a first contact hole region (holes 15″) integrated in cooling inlay 22″. The insulating interspace between the cooling inlay 21 and the further cooling inlay 22 is bridged by a resistance component (shunt 18) applied by SMD soldering. Cooling inlay 22 conducts the current flowing from the semiconductor elements via the resistor to the further contact hole region on cooling inlay 22. The form of cooling inlay 21 is configured such that a plurality of electronic components 17 can be mounted alongside one another in such a way that one type of connection legs of the power components 17 to be cooled is electrically conductively connected to one another and the further type of connection legs is not in electrical contact with the cooling inlay. For this purpose, cooling inlay 21 is preferably provided with cutouts for the connection legs to be insulated of the components 17. Three potential-isolated cooling inlays 22′ are each provided with a contact hole for making contact with an electric motor, for example. The connection legs—carrying a high current—of the power semiconductors 17′ are electrically connected to the surface of the cooling inlays 21 and 22′ (e.g. by soldering). The cooling lugs of the power semiconductors 17′ are likewise respectively connected to cooling inlays by soldering.

The circuit arrangement illustrated in FIG. 1b represents a circuit example of a power stage of a B6 bridge, the latter being illustrated, for simplification purposes, without interference-suppression components that may additionally be required. The bridge circuit illustrated can be used for example for the clocked driving of brushless motors.

FIG. 2a shows a circuit board 16 comprising round cooling inlays 21, 22, wherein the contact holes 22 are provided with contact bores. In FIG. 2b, the cooling inlays from FIG. 2a are additionally populated with busbars 20 and a semiconductor component 17. In both cases, population takes place automatically by means of SMD technology. One of the busbars 20 firstly conducts high currents, and secondly also serves indirectly via an inlay as a heat sink for the heat-generating component 17.

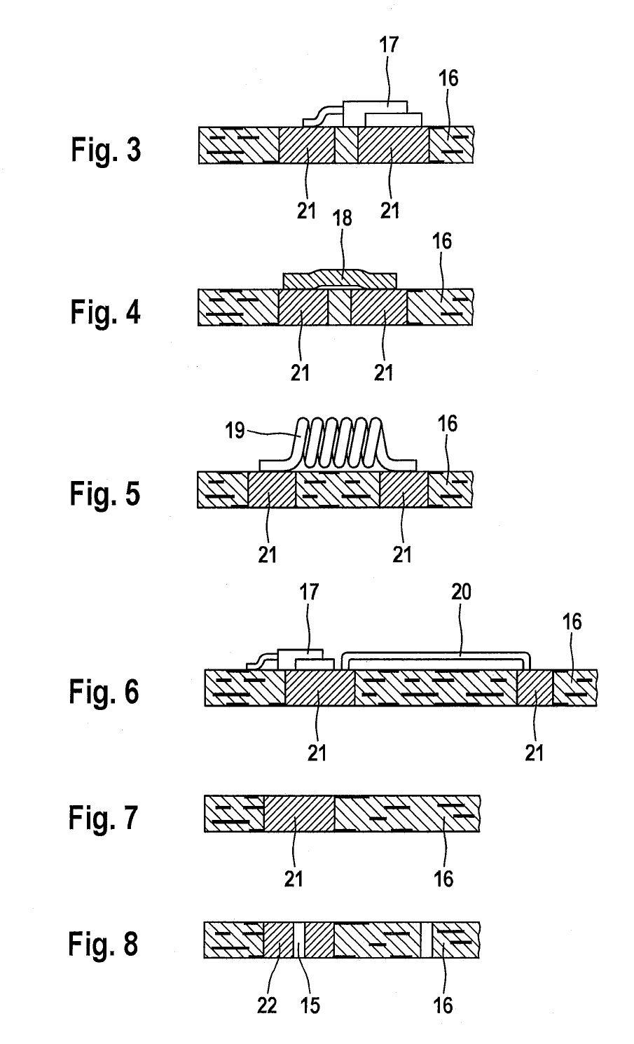

The populated circuit board 16 illustrated in cross section in FIG. 3 comprises two cooling inlays 21 and a soldered-on power semiconductor component 17.

The populated circuit board 16 in FIG. 4 comprises two cooling inlays 21 as in FIG. 3, but with an SMD shunt resistor 18 electrically contact-connected onto the cooling inlays; in the case of FIG. 5, a coil 19 is soldered on, likewise using SMD technology.

In FIG. 6, the cooling area of SMD semiconductor component 17 is placed onto one of the cooling inlays 21. The cooling inlays 21 are electrically and thermally conductively connected to one another via an SMD busbar 20.

Generally, instead of a soldering process, welding of the component contacts for making contact with the circuit board can also be effected, which is advantageous preferably in the case of heavy components, such as coils.

FIG. 7 shows a circuit board 16 comprising a cooling inlay 21 composed of Cu; in this case, it is possible to discern a connection of the cooling inlay to an outer layer of the circuit board that is produced by copper-plating of the circuit board or by tin-plating.

Circuit board 16 in FIG. 8 comprises a cooling inlay 22 with a bore 15 serving as a contact location. By way of example, a press-fit pin or a part of a socket can be inserted into the bore. The further bore illustrated to the right of the bore 15 is a conventional plated-through hole in the circuit board, which, in the example illustrated, connects a conductor track of the topmost and bottommost layers to one another.

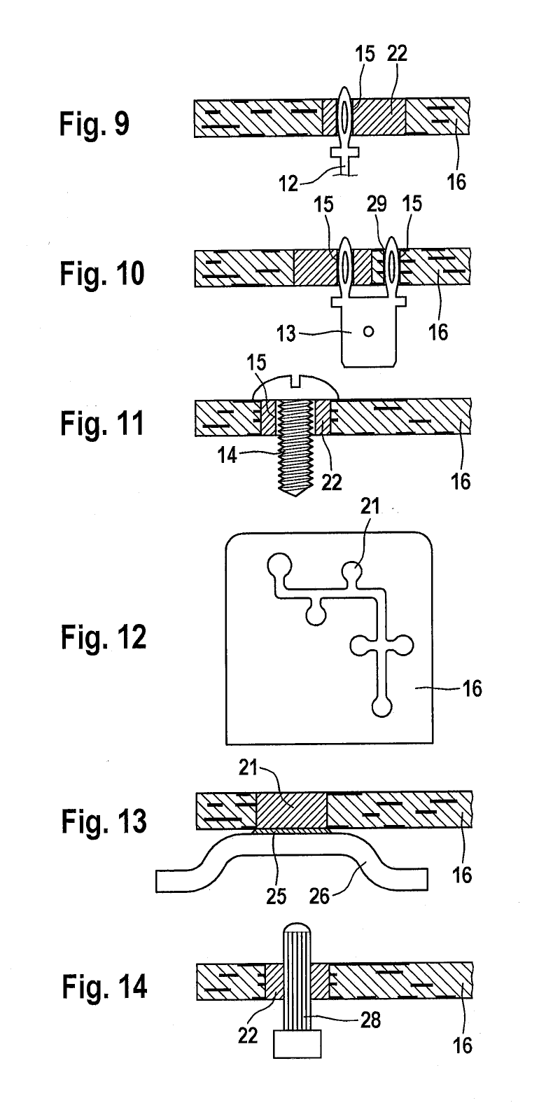

In FIG. 9, a press-fit contact 12 is inserted into a bore 16 in a cooling inlay that is similar to the cooling inlay in FIG. 8.

FIG. 10 shows a variant of a circuit board 16 comprising a bored cooling inlay and a further circuit board bore 29. A multi-pin press-fit contact connector 13 is inserted into the bores present, as a result of which an electrical connection between cooling inlay and one or more conductor tracks is obtained. Inner conductor tracks of the multilayered circuit board 16 can also advantageously be contact-connected in this way. Press-fit contact connector 13 provides firstly for a reliable electrical connection to the circuit board, and secondly also for an improved mechanical linking of the cooling inlay to the circuit board or for a connection of both contacts to a housing which (not illustrated here) carries the press-fit connector. In other words, a very large cooling inlay, preferably suspended from a plurality of press-fit contact connectors 13, can be held securely in this way.

In the example in accordance with FIG. 11, a screw 14 forms the contact element to cooling inlay 22, as a result of which, for example, a current-carrying line can be electrically and mechanically connected to the cooling inlay.

FIG. 12 illustrates a complexly shaped cooling inlay 21 having positively locking, rounded joining points in the manner of a dovetail connection similar to jigsaw pieces, with the aid of which individual parts of the circuit board 16 are connected. This solves the problem of mechanical instability which occurs if a very long inlay is introduced into the circuit board. The mechanical stability of the circuit board is significantly increased by the particular form of the cooling inlay.

In FIG. 13, circuit board 16 likewise comprises a copper inlay 21, wherein a cooling attachment 26 is applied to the copper inlay, which cooling attachment provides for an additional cooling directed toward the outside and can be connected to the cooling inlay 21 in a particularly simple manner by means of a thermally conductive paste 25, a thermally conductive film or a thermally conductive adhesive. Cooling attachment 26 is expediently a simple cooling plate. If the connection does not have to be insulated, a soldering or welding connection is also appropriate. In the case of a soldering or welding connection, in addition to the cooling effect the contact-connection can also be utilized as a low-impedance high-current connection.

The circuit board 16 illustrated in FIG. 14 comprises a bored copper inlay 22, into which a conventional socket contact 28 (e.g. multiple-spring wire plug) is inserted. A particularly simple electrical connection from outside to the circuit board can be performed in this way.

1-10. (canceled)

11. A circuit board arrangement suitable for population with at least one electronic power component to be cooled, said circuit board arrangement comprising:
at least one low-current conductor track,
wherein the circuit board comprises a nonconductive material including at least one cooling inlay embedded into the circuit board and serving for cooling the electronic power component,
wherein the cooling inlay forms, at least in part, a high-current conducting element for the at least one electronic power component,
wherein a conducting cross section or a current-carrying capacity of the high-current conducting element is greater than a conducting cross section or a current-carrying capacity of the low-current conductor track, and
wherein the high-current conducting element is utilized and/or concomitantly utilized for making electrical contact with the electronic power component.

12. The arrangement as claimed in claim 11, wherein the high-current conducting element is connected to at least one further electronic power component or a high-current contact-connection in an electrically conductive and low-impedance manner.

13. The arrangement as claimed in claim 11, wherein the high-current conducting element conducts the current via a cooling inlay and via at least one emplaced high-current bridge.

14. The arrangement as claimed in claim 13, wherein the at least one emplaced high-current bridge is embodied as an electrical component capable of automatic placement.

15. The arrangement as claimed in claim 14, wherein an electrical contact-connection of the high-current conducting element to the electrical component and/or the low-current conductor track is effected by one or a plurality of press-fit contacts.

16. The arrangement as claimed in claim 14, wherein an electrical contact-connection of the high-current conducting element to the electrical component or a further cooling element is effected by surface mount technology (SMT) method.

17. The arrangement as claimed in claim 11, wherein the high-current conducting element is directly electrically connected to a low-current conductor track, wherein the direct electrical connection can be effected by a pressure contact, soldering, welding, or calking.

18. The arrangement as claimed in claim 11, wherein the high-current conducting element includes multiple branches and/or curves and/or is provided with multiple connection locations for electrical components.

19. The arrangement as claimed in claim 11, wherein the high-current conducting element has one or a plurality of joining points which are configured to be used to form positively locking connections to the conductor track or parts thereof, wherein the joining points constitute dovetail connections.

20. The use of the circuit board arrangement of claim 11 in the field of motor vehicle electronics.

21. A method for producing a circuit board arrangement as claimed in claim 11, comprising the steps of:
press-fitting at least one cooling inlay into a circuit board arrangement, and
populating the circuit board arrangement with electrical components according to a surface mount technology (SMT) method.

22. The arrangement as claimed in claim 11, wherein the circuit board arrangement is a multilayered circuit board arrangement.
